(19) United States
(12) Patent Application Publication
(10) Pub. No.: US 2026/0360460 A1
(43) Pub. Date: Nov. 12, 2026

(54) PROTECTION FOR CIRCUIT DEFECT

(71) Applicant: Micron Technology, Inc., Bosie, ID (US)

(72) Inventor: Shigekazu Yamada, Tokyo (JP)

(73) Assignee: Micron Technology, Inc., Boise, ID (US)

(21) Appl. No.: 19/651,517

(22) Filed: Apr. 17, 2026

Related U.S. Application Data
(60) Provisional application No. 63/803,183, filed on May 9, 2025.

(51) Int. Cl. G11C 29/00; G11C 16/26

(52) U.S. Cl. CPC G11C 29/70; G11C 16/26

(57) ABSTRACT

A memory device is provided. The device includes an array of memory cells having multiple memory blocks. The memory blocks include a first memory block. The device includes a memory controller; and a first switch connected to the first memory block. The memory controller is configured to select or unselect the first memory block via the first switch. The device includes a first ground line shared among the plurality of memory blocks; and a second switch connected between the first ground line and the first switch. The second switch is configured to electrically couple the first memory block to the first ground line via the first switch. The controller is configured to cause the second switch to activate, and upon activating, disconnect the first memory block from the first ground line shared among the plurality of memory blocks.

### CROSS REFERENCE TO RELATED APPLICATIONS

This application claims priority to U.S. Application No. 63/803,183, filed on May 9, 2025, and is entitled “PROTECTION FOR CIRCUIT DEFECT,” the content of which is incorporated by reference herein in its entirety for all purposes.

### TECHNICAL FIELD

This disclosure relates to one or more systems for memory, including techniques for protecting a memory device from circuit defects such as shorts.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory cells in a memory device, in accordance with examples as disclosed herein.

FIG. 3 is a block diagram of an example apparatus for implementing one or more systems and for performing one or more methods described herein, in accordance with examples as disclosed herein.

FIG. 4 is a diagram illustrating a configuration of a memory device having a ground line shared between a plurality of memory blocks.

FIG. 5A is a diagram illustrating an example memory device having an isolation switch to protect the memory device from defects like shorts according to some embodiments.

FIG. 5B is a diagram illustrating an example circuit including a latch according to some embodiments.

FIG. 6 is a diagram illustrating another example memory device having an isolation switch and a ground-line switch to protect the memory device from defects like shorts according to some embodiments.

FIG. 7 is a flowchart illustrating an example method for protecting a memory device from defects like shorts according to some embodiments.

### DETAILED DESCRIPTION

A memory device typically includes an array of memory cells. The array can include many memory blocks (referred to as simply blocks). For the purpose of area reduction, the memory device usually has an electrical ground line shared among the memory blocks. The memory device further includes many switches connected to the memory blocks. Each switch is configured to select or unselect a corresponding memory block under the control of control logic (e.g., a memory controller). For an unselected memory block, the corresponding switch connects the unselected memory block to the ground line shared among the memory blocks.

In this architecture, when a memory block is defective, for example has one or more shorts in the circuitry, the corresponding switch may still treat a memory block as unselected and thus connects the memory block to the ground line. In the defective memory block, the short-circuit may be from a circuit element (e.g., a pillar, a select gate drain (SGD), a bit line, a word line, etc.) to another element having a positive voltage. Because the ground line is shared among many memory blocks, the positive voltage, due to the short-circuit caused by the defective memory block, can travel to the ground line and further to a non-defective memory block, and therefore cause extra leakage current. The extra leakage current in turn may affect more non-defective memory blocks in a negative manner. For example, depending on the strength of the ground line, positive voltages may travel to the select gate drain (SGD) transistors in non-detective blocks. An SGD transistor is connected to a bit line. If an SGD transistor is turned off, the bit line has no current flowing. If the positive voltages reach the SGD transistors, they may cause undesired bit line leakage during read and program verify operations. Another common defect in the memory block is the shut-off leakage caused by the SGD. The SGD may not be robust enough and therefore it does not turn off completely for an unselected memory block. Therefore, leakage current may flow from the bit line to the unselected memory block. Memory sensing operations like read or program verify of another selected memory block may be negatively affected by this shut-off leakage defect. Accordingly, the aforementioned circuitry defects may undesirably reduce the memory device’s operational performance. Therefore, there is a need for techniques to protect a memory device from defects such as shorts and shut-off leakage.

The present disclosure is directed to circuitry including an isolation switch connected between the shared ground line and a memory block. The isolation switch, in some examples, can be in addition to another switch that is used to select or unselect a memory block. The isolation switch can be controllably activated to disconnect the memory block from the shared ground line. As a result, in situations where the memory block is defective (e.g., shorted to ground), the isolation switch can isolate the defective memory block from other non-defective memory blocks, thereby reducing noise or disturbances caused by the defective memory block. Moreover, the isolation switch can reduce leakage current by reducing the likelihood of the positive voltage travel caused by defects (e.g., shorts).

In this disclosure, a method to protect a memory device from defects like shorts is also described. The method can be performed by the memory device. The memory device includes many memory blocks, a memory controller, an isolation switch, a latch, and a ground line shared between the memory blocks. The memory blocks include a first memory block and other memory blocks. In this disclosed method, the memory device can store data representing whether the first memory block is a defective memory block in a latch. Based on the stored data, the latch provides a control signal to the isolation switch to connect the first memory block to the ground line or disconnect the first memory block from the ground line shared among the plurality of memory blocks. The circuitry and the method are further described in greater detail below.

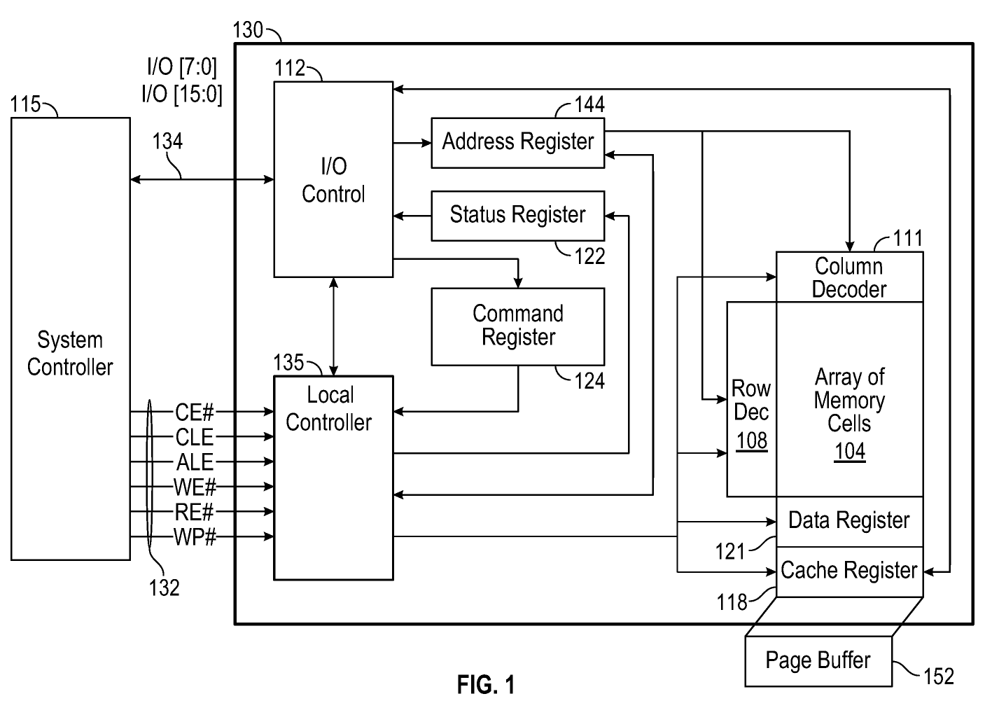

FIG. 1 is a simplified block diagram of a memory device 130 in communication with a system controller 115 of a memory system. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 144 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115. For example, the local controller 135, on its own or in response to a command provided by external system controller 115, is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

In some examples, local controller 135 communicates with the external system controller 115, which may be a host controller (e.g., an UFS or eMMC controller, or a CPU communicating with local controller 135) located in a host system or a memory system controller located in a memory system. Local controller 135 can be disposed on the same semiconductor die as the memory array (e.g., array 104), and a separate system controller 115 can be disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. One or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some examples, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

As shown in FIG. 1, memory device 130 receives various control signals via local controller 135 from system controller 115 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 144. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

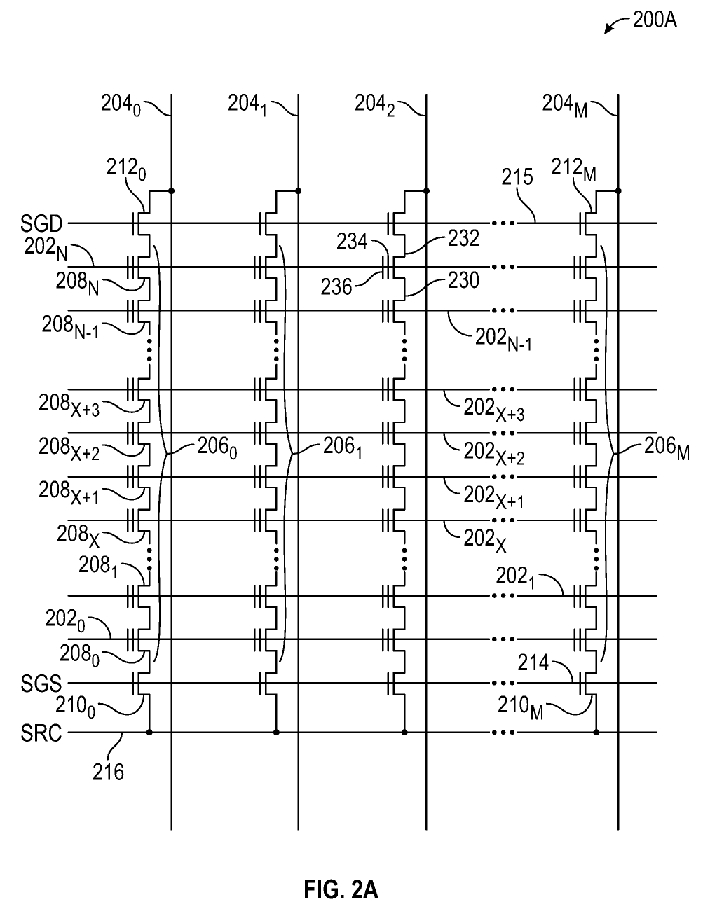

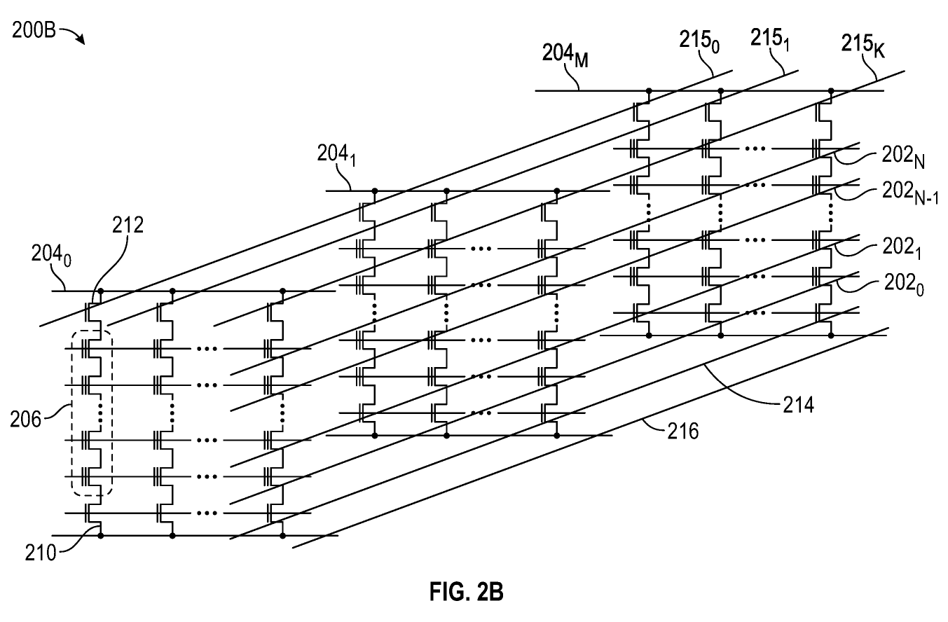

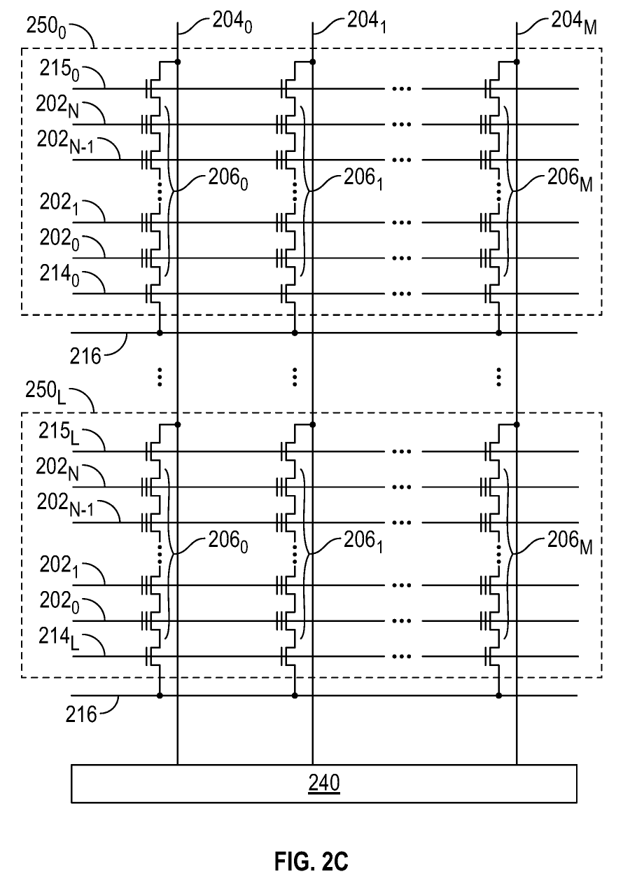

FIGS. 2A-2B are example schematics of portions of an array of memory cells 200A, such as a NAND memory array. Array of memory cells 200A may be an example of memory array 104 of a memory device 130 as described with reference to FIG. 1 according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In other embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. The blocks 250 are shown in FIG. 2C using dashed lines to illustrate that certain numbers of memory cells can be group together for certain operations. For instance, blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204. In one example, buffer portion 240 can be a part of page buffer 152. As described below, multiple buffer portions 240 may collectively form a page buffer 152.

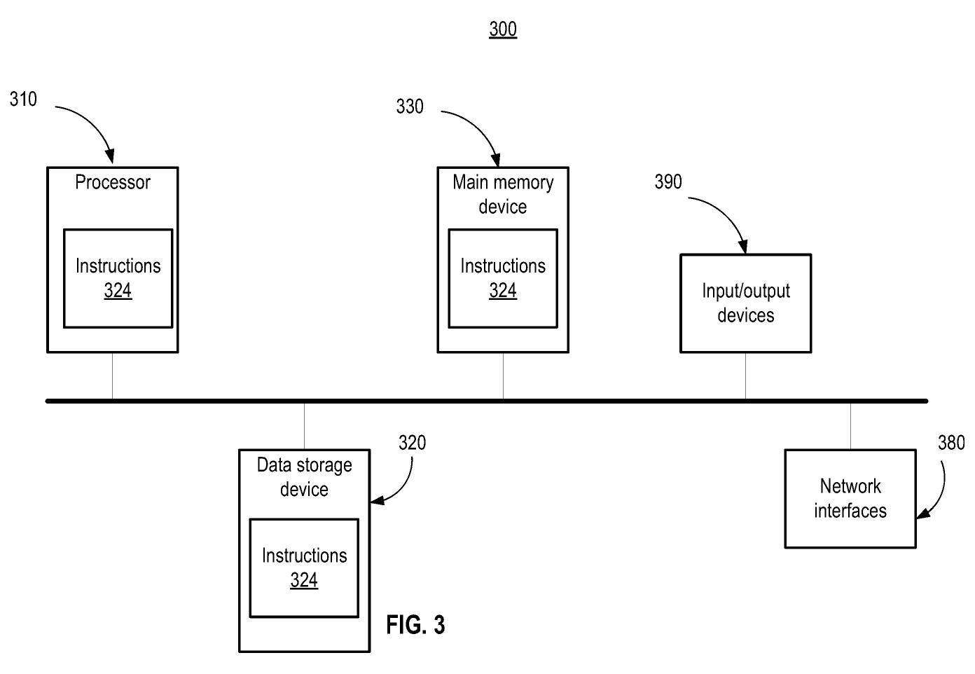

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and blocks described herein, including one or more of the blocks of at least some of the FIGS. 1-7, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

Apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 if the computer program instructions are desired. For example, processor 310 may be used to implement one or more components and systems described herein, such as system controller 115 and/or local controller 135 (shown in FIG. 1). Thus, the blocks of processes in at least some of FIGS. 1-7 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the processes or blocks discussed herein in connection with at least some of FIGS. 1-7. Accordingly, by executing the computer program instructions, processor 310 executes an algorithm defined by the processes or blocks of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

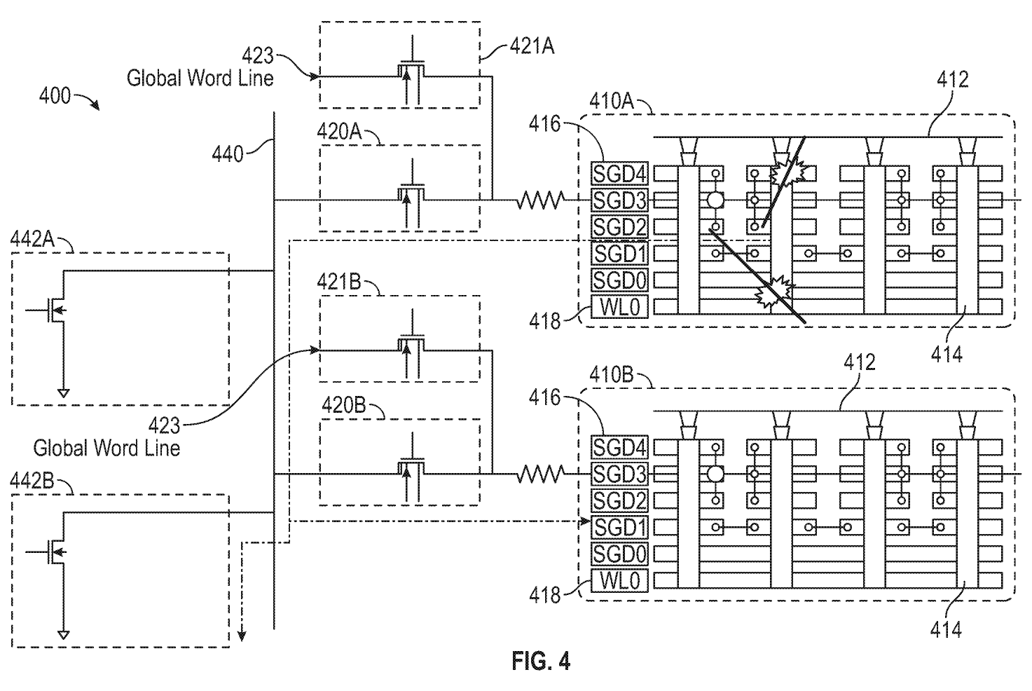

FIG. 4 is a diagram illustrating a configuration of a memory device 400 (e.g., memory devices 130 shown in FIG. 1) having a ground line shared among a plurality of memory blocks (e.g., blocks 250 shown in FIG. 2C). Under certain circumstances, the configuration of FIG. 4 may be susceptible to circuitry defects like shorts. The memory device 400 includes an array of memory cells (e.g., memory array shown in FIGS. 2A and FIG. 2B). The array of memory cells shown in FIG. 4 includes two example memory blocks 410A and 410B (collectively as 410). While FIG. 4 illustrates an example of two memory blocks 410A and 410B, it is understood that more memory blocks 410 can be included in the memory device 400. For the purposes of device area reduction, the memory device 400 further includes a ground line 440 shared among multiple memory blocks 410. As shown in FIG. 4, there are a plurality of grounder transistors 442A and 442B (collectively as 442) connected to the shared ground line 440. Usually, the ground line 440 has a voltage of, for example, zero volt. Because of the shared nature of the ground line 440, in an erase operation, to prevent unselected blocks from being erased, the shared ground line 440 may be switched to a positive voltage level that is sufficiently high (e.g., Vcc) via the plurality of grounder transistors 442. For instance, during the erase operation, the pillars of the memory cells in an unselected memory block 410A are biased to a high positive voltage (e.g., 22V) via the coupling with the source line (SRC). To prevent the unselected block from being erased, the local SGD/SGS transistors need to be biased to the same high voltage, thereby requiring the shared ground line 440 to go to a sufficiently high voltage if the switch 420A (e.g., a string driver) stays activated to connect the shared ground line 440 to the SGDs of the unselected block 410A. The SGD transistors shown in FIG. 4 can be the same as or similar to those SGD transistors in FIG. 2A.

With continued reference to FIG. 4, the memory device 400 further includes a plurality of switches 420A and 420B (collectively as 420) connected to the memory blocks 410. Switches 420A and 420B are sometimes also referred to as string drivers. Only two string drivers are shown in FIG. 4, but more can be used for other memory blocks. Each of the switches 420 is configured to select or unselect a corresponding memory block 410 under the control of control logic. In this disclosure, the control logic in some examples can include the controllers (e.g., local controller, system controller, etc.). In other examples, the control logic can further include other blocks or circuitry (e.g., sense amplifiers, latches, buffers, registers, decoders, etc.), but not the array of memory cells. The control logic is not shown in FIG. 4, but can be for example local controller 135 shown in FIG. 1. Under the control of the control logic, a switch 421 (e.g., switch 421A or 421B) can connect a corresponding selected memory block 410 to a common global word line 423. If a memory block 410A and/or 410B is selected, the common global word line 423 is electrically coupled to the local word line of the selected memory block via switch 421A and/or switch 421B. As shown in FIG. 4, if a memory block 410A and/or 410B is unselected, each of the switches 420A and/or 420B connects the corresponding unselected memory block 410A and/or memory block 410B to the ground line 440. Each of the memory blocks 410 further include one or more select gate drains (SGDs) 416. As shown in FIG. 4, each of the switches 420 is connected between the SGDs 416 of a corresponding memory block 410 and the ground line 440.

As shown in FIG. 4, if the memory block 410A becomes defective, for example, has one or more shorts, the switch 420A may still treat the memory block 410A as unselected and connects the memory block 410A to the shared ground line 440. For example, the defective memory block 410A may have one or more of: a short between a pillar 414 and an SGD 416, a short between an SGD 416 and a bit line 412, a short between a source line (not shown) and an SGD 416, and a short between a word line 418 and an SGD 416. Some of the shorts are connected to a positive voltage (e.g., from a bit line 412 or a word line 418). As shown in FIG. 4, because the ground line 440 is shared among the memory blocks 410A and 410B, the positive voltage caused by the one or more shorts from the defective block 410A can travel to the grounder transistor 442A on the ground line 440 and further to the non-defective memory block 410B. The memory block 410B may have its SGDs 416 turned off, but because of the positive voltage supplied to the SGDs 416 (e.g., via switch 420B, which connects the block 410B to the shared ground line 440), the SGD 416 of the block 410B may therefore cause undesired extra leakage current.

In some situations, the extra leakage current in turn may affect more non-defective memory blocks in a negative manner. For example, depending on the strength of the ground line 440, positive voltages may travel to SGD transistors in non-defective blocks (e.g., another non-defective block not show, but similar to block 250 described above), and therefore causing undesired bit line leakage during read and program verify operations. Another common defect in the memory block is the shut-off leakage caused by the SGD 416. Some of the SGD 416 may not be robust enough and therefore it does not turn off completely for an unselected memory block (e.g., 410A or 410B). Therefore, leakage current may flow from the bit line 412 to the unselected memory block (e.g., 410A or 410B). Memory sensing operations like read or program verify of another selected memory block may be negatively affected by this shut-off leakage defect. Accordingly, the aforementioned circuitry defects may undesirably reduce the memory device’s operational performance, and in some situations affect the data accuracy or even cause data corruption. Therefore, there is a need for techniques to protect a memory device from defects such as shorts and shut-off leakage.

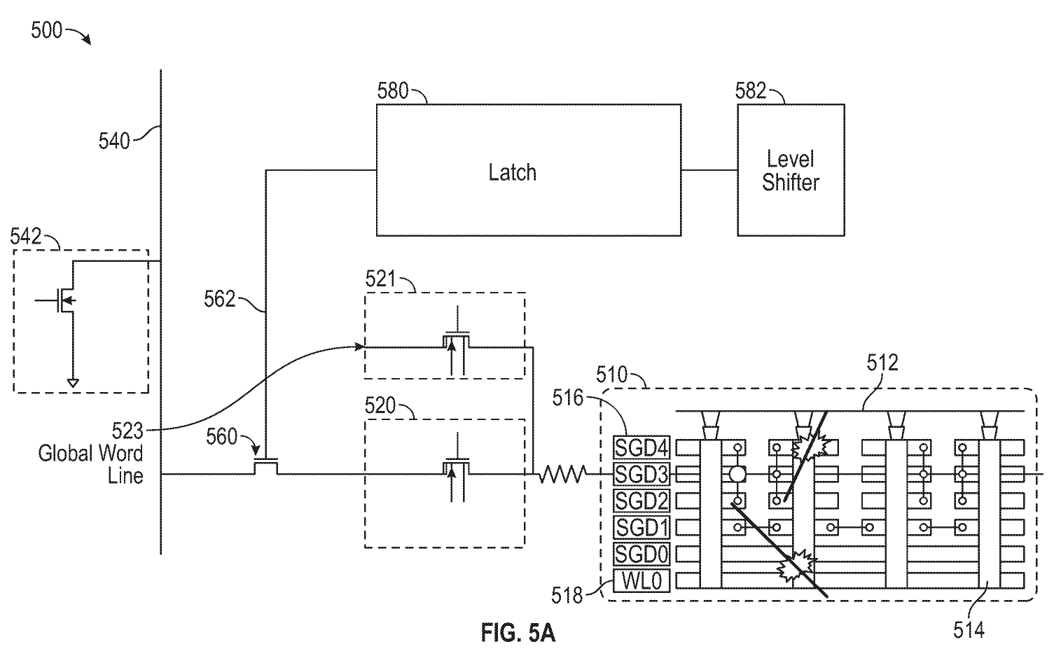

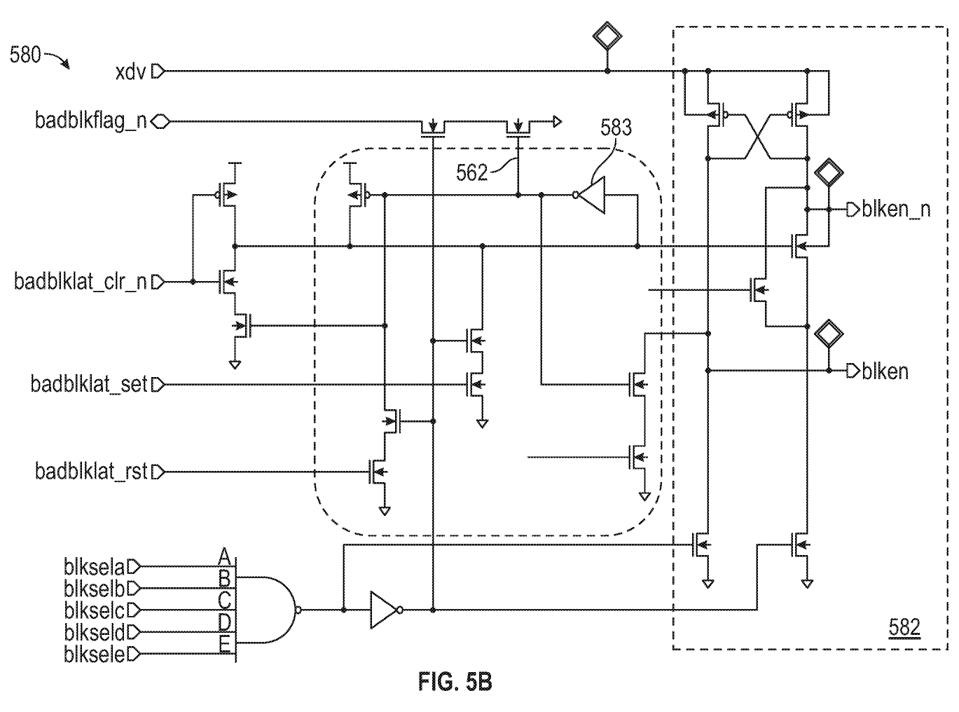

FIG. 5A is a diagram illustrating an example memory device 500 having an isolation switch 560 to protect the memory device 500 from defects such as shorts according to some embodiments. The memory device 500 (e.g., memory devices 130 shown in FIG. 1) comprises an array of memory cells (e.g., memory array 104, 200A, or 200B shown in FIGS. 1, 2A, and 2B). The array of memory cells of device 500 includes many memory blocks (e.g., blocks 250 shown in FIG. 2C). FIG. 5A illustrates one such memory block 510. It is understood that FIG. 5A is simplified and therefore it can include more memory blocks in addition to memory block 510. The memory device 500 further includes a memory controller (e.g., local controller 135, shown in FIG. 1) and a first switch 520 connected to the memory block 510. In some examples, the first switch 520 (and switch 521 shown in FIG. 5) can be used to implement a part of the row decode circuitry 108 shown in FIG. 1. The first switch 520 is also referred to as a string driver and configured to select or unselect the memory block 510 for operations (e.g., read, program verify, etc.) under the control of the memory controller.

With reference to FIG. 5A, the memory block 510 can further include one or more select gate drains (SGDs) 516. As shown in FIG. 5A, the first switch 520 of the memory block 510 is connected to the SGDs 516. In some examples, the one or more SGDs 516 include a plurality of ganged SGDs having respective control terminals connected together. Ganged SGDs connected in this manner are connected in parallel such that they can be controlled to turn on and off together. For the purpose of reducing circuit area, the memory device 500 comprises a first ground line 540 shared among the memory blocks including the memory device 500.

In some situations, memory block 510 may become defective. For example, as described above, short-circuit conditions may happen among various elements of the block 510. The block 510 may become defective due to various reasons including manufacturing-induced defects, operation-induced defects, and reliability-induced defects. To protect the memory device 500 from circuit defects in a defective memory block 510, as shown in FIG. 5A, the memory device 500 is configured to further include a second switch 560 connected between the first ground line 540 and the first switch 520. The second switch 560 is an isolation switch and configured to isolate the memory block 510 from other memory blocks in the memory device 500, if the first memory block 510 becomes a defective memory block. As illustrated in FIG. 5A, the defective memory block has one or more of: a short between a pillar 514 and a select gate 516, a short between a select gate 516 and a bit line 512, a short between a source line (not shown) and a select gate 516, and a short between a word line 518 and a select gate 516.

In some examples, the second switch 560 is controllably activated if the first memory block 510 is a defective memory block. For example, second switch 560 can be controlled (activated or deactivated) by the control logic (e.g., local controller 135). After activation, the second switch 560 disconnects the memory block 510 from the first ground line 540 shared among many memory blocks of device 500. As a result, the second switch 560 isolates the memory block 510 from other memory blocks in memory device 500 and therefore shuts off noise or disturbances caused by the defective memory block 510. As described above, if there are circuit defects like short in a memory block, a positive voltage may be caused by the one or more shorts in the defective block. The positive voltage may come from a bit line, for example. With the second switch 560 turned off, the positive voltage cannot travel to other memory blocks in the memory device 500 via the first ground line 540 shared among many memory blocks in device 500, thereby protecting the memory device 500 from shorts and excessive leakage currents.

With continued reference to FIG. 5A, the second switch 560 includes a first terminal (e.g., a drain terminal) connected to the first switch 520, a second terminal (e.g., a source terminal) connected to the first ground line 540, and a control terminal (e.g., a gate terminal) configured to receive a first control signal 562. In some embodiments, the second switch 560 comprises a low-voltage NMOS (N-type metal-oxide semiconductor) transistor. The low-voltage NMOS transistor has a size that is smaller than a transistor of the first switch 520. Therefore, a small area in the first memory block 510 can accommodate the second switch 560. In addition, because the second switch 560 can shut off noise or disturbance coming from a defective memory block, fewer grounder transistors or a smaller grounder transistor (e.g., one grounder transistor 542 shown in FIG. 5A) are required for the first ground line 540 shared among the plurality of memory blocks, thereby further reducing area and saving cost.

With continued reference to FIG. 5A, the memory device 500 further includes a latch 580 coupled to the second switch 560 to provide the first control signal 562 to the second switch 560. FIG. 5B is a diagram illustrating an example circuit comprising the latch 580 according to some embodiments. As shown in FIG. 5A, the latch 580 is configured to store data representing whether the first memory block 510 is a defective memory block. Based on the stored data representing whether the first memory block 510 is a defective memory block, the latch 580 provides a first control signal 562 to the second switch 560 to connect the memory block 510 to the first ground line 540 or disconnect the memory block 510 from the first ground line 540. For example, if the memory block 510 is a defective memory block, the latch 580 provides the first control signal 562 to the second switch 560 to disconnect the memory block 510 from the first ground line 540. If the memory block 510 is not a defective memory block, the latch 580 provides the first control signal 562 to the second switch 560 to connect the memory block 510 to the first ground line 540. In some embodiments, the first control signal 562 is an internal signal of the latch 580. In other words, the first control signal 562 may not be an input or an output signal of the latch 580. An internal signal of latch 580 may or may not have the same voltage level as the input or output signals of latch 580. An example of latch 580 is described below in FIG. 5B.

As shown in FIGS. 5A and 5B, the memory device 500 further includes a level shifter 582 coupled to the latch 580 to receive an output signal of the latch 580. As described above, an internal signal of latch 580 may be used to control the second switch 560 to disconnect the first memory block 510 from the shared ground line 540. This internal signal may be the internally-latched signal 562 (e.g., the output signal of inverter 583). As shown in FIG. 5B, latch 580 may receive inputs such as a defective block flag signal (e.g., denoted by badblkflag_n) indicating a particular block is a defective block. This defective block flag signal can have a high value (e.g., a digital “1” representing a high voltage like Vcc) that is stored in latch 580. This stored value may pull down the input of inverter 583, and therefore, the output of the inverter 583 has a high value (e.g., a digital “1”). The output of the inverter 583 thus can be used as the control signal 562 for controlling the second switch 560. Latch 580 may also receive other input signals such as a clock input (denoted as badblklat_clr_n), a set input signal (e.g., denoted as badblklat_set), and a reset input signal (e.g., denoted as badblklat_rst). In some examples, latch 580 is further connected to a level shifter 582. Latch 580 may receive a power supply voltage and operates in one voltage domain (e.g., a digital Vcc domain having a power supply voltage of about 1.5V). Other parts of the memory device may operate in another voltage domain having a higher power supply voltage (e.g., 3V). Therefore, the level shifter 582 is configured to shift a voltage level of the internal signal 562 of the latch 580 to a different voltage level. In the example shown in FIG. 5B, the level shifter 582 receives the input signals including the internal signal 562 and block select signals (e.g., denotes as blksela-blksele) and provides block enable signals (e.g., denoted as blken_n and blken) in a different voltage domain. Level shifter 582 operates at this different voltage domain by receiving a different power supply (e.g., denoted as xdv). Although FIG. 5B illustrates a specific implementation of latch 580, it should be recognized that various other circuit configurations may be implemented to achieve the described functionality. In particular, latch 580 can be configured to receive an indication of whether the memory block 510 is defective. In response to receiving an indication that the block 510 is defective, the latch 580 is configured to activate the second switch 560 to isolate the block 510 from the shared ground line 540. In response to receiving an indication that the block 510 is not defective, latch 580 is configured to control the second switch 560 to electronically couple the memory block 510 to the shared ground line 540.

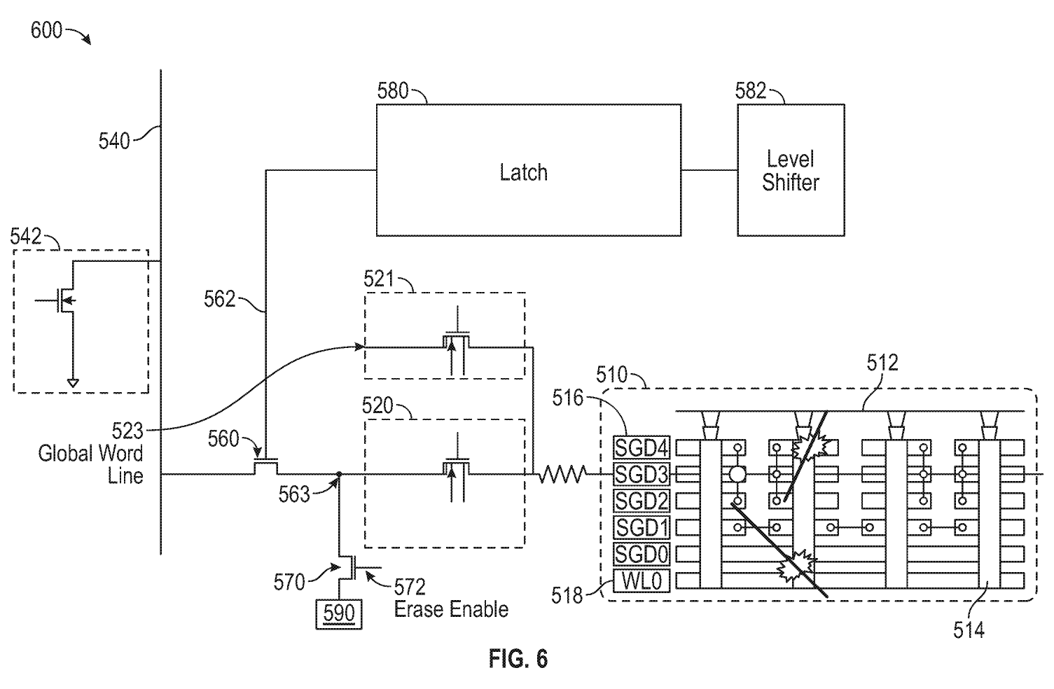

FIG. 6 is a diagram illustrating another example memory device 600 having an isolation switch 560 and a ground-line switch 570 to protect the memory device from defects like shorts according to some embodiments. The memory device 600 can be substantially the same or similar to memory device 500 described above, except includes the ground-line switch 570. Thus, the same or similar elements (e.g., ground line 540, latch 580, level shifter 582, switch 560) are not repeatedly described here.

As shown in FIG. 6, similar to memory device 500, the memory device 600 includes a second switch 560 connected between the first ground line 540 and the first switch 520. As described above, the second switch 560 can include a low-voltage NMOS transistor or transistors. In some examples, a high voltage operation, e.g., an erase operation, may occur in memory device 600. The high voltage operation may impose a high voltage (e.g., 20V, 30V, etc.) at a node 563 between the first switch 520 and the second switch 560. Such a high voltage at node 563 may cause break down of the second switch 560. As described above, control signal 562 is provided from latch 580 to the control terminal (e.g., the gate terminal) of switch 560. Signal 562 may be an internal signal of latch 580 and is a digital signal in the low digital power supply voltage domain. Thus, when the node 563 receives a high voltage from another voltage domain, the voltage difference imposed on switch 560 (e.g., imposed across the gate terminal and the source terminal of a transistor of switch 560) may be large enough to break down the transistor’s oxide layer or a semiconductor junction, resulting in device failure. To prevent the second switch 560 from breaking down and protect the memory device 600 from circuit defects like shorts, as shown in FIG. 6, the memory device 600 further includes a third switch 570 coupled to the second switch 560 and the first switch 520. The third switch 570 is a ground-line switch and can be controllably activated based on a second control signal 572. The second control signal 572 represents an operation having a voltage exceeding a breakdown threshold of the second switch 560. In one example, such an operation can be an erase operation. An erase operation typically uses large enough voltage to erase existing data stored in the memory cells and restore all memory cells being erased to a logical state of L0. Thus, in one example, second control signal 572 can be the same as, or a derived signal of, the erase operation enable signal. As such, when the erase operation is performed in the memory device 600, the third switch 570 is also turned on to connect node 563 to an electrical ground via, for example second ground line 590. For other memory operations that do not involve high voltage, the third switch 570 may not be turned on and therefore, node 563 is not connected to the electrical ground.

After activation, the third switch 570 connects the memory block 510 to a second ground line 590. As shown in FIG. 6, in one example, the second ground line 590 is not shared among the plurality of memory blocks of device 600. As a result, by using the third switch 570, even if a high voltage occurs during a particular operation (e.g., an erase operation) and is passed onto node 563, second switch 560 is still protected from breaking down because node 563 is grounded to the second ground line 590. Thus, by adding third switch 570, it prevents the second switch 560 from breaking down, which in turn protects the memory device 600 from short-circuit defects and leakage in the memory block 510.

With reference to FIG. 6, the third switch 570 comprises a first terminal connected to the first switch 520, a second terminal connected to the second ground line 590, and a control terminal configured to receive the second control signal 572. In some embodiments, similar to the second switch 560, the third switch 570 also includes a low-voltage NMOS transistor. The low-voltage NMOS transistor has a size that is smaller than a transistor of the first switch 520. Therefore, a small area in the memory block 510 can accommodate the two low-voltage NMOS transistors. In other examples, the third switch 570 may include a high-voltage transistor.

Similar to the memory device 500, the memory device 600 also includes a latch 580 coupled to the second switch 560, and a level shifter 582 coupled to the latch 580 to receive an output signal of the latch 580. The latch 580 is configured to store data representing whether the first memory block 510 is a defective memory block. Based on the stored data representing whether the first memory block 510 is a defective memory block, the latch 580 provides a first control signal 562 to the second switch 560 to connect the memory block 510 to the first ground line 540, or disconnect the memory block 510 from the first ground line 540. In some situations, the routing distance from switch 520 to switch 560 may be long due to layout-constraint. The internal signal at node 563 between switch 520 and switch 560 could be electrically coupled-up by, for example, a common source (SRC) plate (not shown) in memory device 600. As a result, node 563 may have a high voltage, which may break down the second switch 560 (e.g., a low-voltage NMOS transistor). By using the third switch 570, the internal signal between switch 520 and switch 560 can also be grounded to the second ground line 590, regardless of whether an operation having a voltage exceeding a breakdown threshold of the second switch 560 is being performed, thereby preventing the second switch 560 from breaking down.

In the above example, each of switch 560 and/or switch 570 can include a single low-voltage NMOS transistor. In some embodiments, each of switch 560 and/or switch 570 can be implemented using a grounder transistor 542. As described above, in a conventional configuration shown in FIG. 4, there may be many grounder transistors 442 required. In the examples disclosed in FIGS. 5A and 6, due to the use of the second switch 560 (e.g., the isolation switch) and the third switch 570, the number of grounder transistors 542 can be reduced (in some cases significantly reduced). Each of switch 560 and/or switch 570 can be implemented with the use of a single grounder transistor 542. In some examples, if the strength of switch 560 and/or 570 is not enough (e.g., not enough to shut off leakage entirely), the switch 560 and/or 570 can use transistors sized equivalent of two or more of the grounder transistors 542. In some examples, the increase of the size of switches 560 and/or 570 is minimum, and therefore the adding of switches 560 and/or 570 does not increase the total layout area. In some situations, the total layout area may be reduced because fewer ground transistors are required.

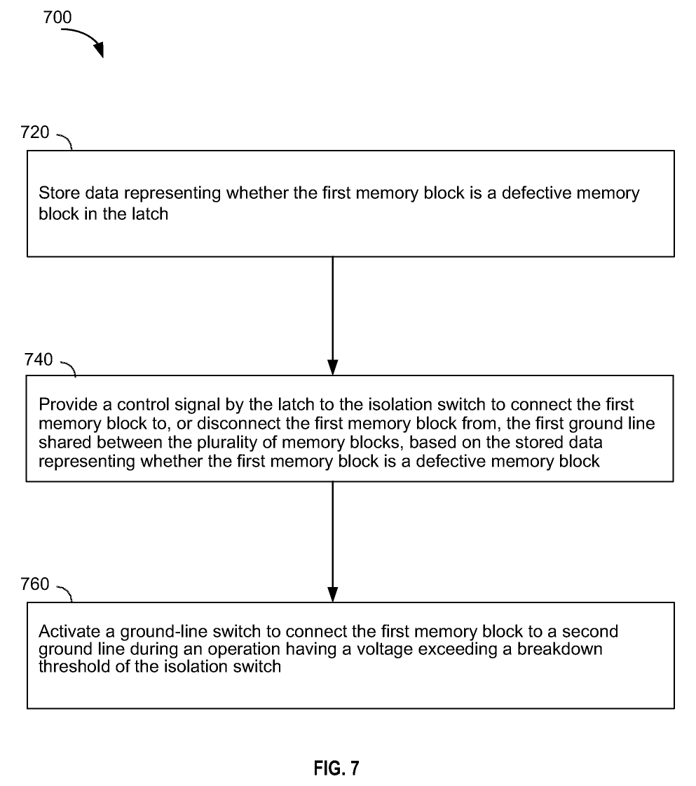

FIG. 7 is a flowchart illustrating an example method 700 for protecting a memory device from defects like shorts according to some embodiments. The memory device (e.g., memory devices 130, 500, or 600 shown in FIGS. 1, 5A, and 6) comprises many memory blocks (e.g., blocks 250 shown in FIG. 2C, memory block 510 shown in FIGS. 5A and 6), a memory controller (e.g., local controller 135 shown in FIG. 1), an isolation switch (e.g., second switch 560 shown in FIGS. 5A and 6), a latch (e.g., latch 580 shown in FIGS. 5A and 6), and a first ground line (e.g., first ground line 540 shown in FIGS. 5A and 6) shared between the plurality of memory blocks. The plurality of memory blocks includes a first memory block (e.g., memory block 510 shown in FIGS. 5A and 6). The first memory block further includes one or more SGDs (e.g., SGDs 516 shown in FIGS. 5A and 6). In some examples, the one or more SGDs include a plurality of ganged SGDs having respective control terminals connected together. In other examples, SGD 516 may include a single SGD transistor or other configurations of select transistors.

In block 720 of method 700, the memory controller stores data representing whether the first memory block is a defective memory block in the latch. In some embodiments, the defective memory block has one or more of: a short between a pillar and a select gate, a short between a select gate and a bit line, a short between a source line and a select gate, and a short between a word line and a select gate.

In block 740 of method 700, based on the stored data representing whether the first memory block is a defective memory block, the latch provides a control signal (e.g., control signal 562) to the isolation switch (e.g., switch 560) to connect the first memory block (e.g., block 510) to the first ground line (e.g., ground line 540), or disconnect the first memory block from the first ground line shared between the plurality of memory blocks of a memory device (e.g., device 500 or 600).

In some embodiments, the isolation switch includes a first terminal (e.g., a drain terminal) connected to a first switch (e.g., switch 520), a second terminal (e.g., a source terminal) connected to the first ground line (e.g., ground line 540), and a control terminal (e.g., a gate terminal) configured to receive the control signal (e.g., control signal 562). The first switch is connected to the first memory block. The first switch is configured to select or unselect the first memory block under control of the memory controller. In some embodiments, the isolation switch comprises a low-voltage NMOS transistor. The low-voltage NMOS transistor has a size that is smaller than a transistor of the first switch.

In some embodiments, the control signal is an internal signal of the latch (e.g., latch 580). The control signal may not be an input or an output signal of the latch. In some embodiments, the memory device further comprises a level shifter (e.g., level shifter 582) coupled to the latch to receive an output signal of the latch. The level shifter is configured to shift a voltage level of the output signal of the latch to a different voltage level.

In block 760 of method 700, during an operation having a voltage exceeding a breakdown threshold of the isolation switch, the controller (e.g., local controller 135) activates a ground-line switch (e.g., switch 570) to connect the first memory block to a second ground line (e.g., ground line 590). The second ground line is not shared between the plurality of memory blocks. In some embodiments, the operation has a voltage exceeding the breakdown threshold of the second switch comprises an erase operation.

In some embodiments, the ground-line switch (e.g., switch 570) includes a first terminal (e.g., a drain terminal) connected to the first switch (e.g., switch 520), a second terminal (e.g., source terminal) connected to the second ground line (e.g., ground line 590), and a control terminal (e.g., a gate terminal) configured to receive a control signal (e.g., signal 572) representing the operation having a voltage exceeding a breakdown threshold of the isolation switch. In some embodiments, the ground-line switch is a low-voltage NMOS transistor. The low-voltage NMOS transistor has a size that is smaller than a transistor of the first switch.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “controller” is used interchangeably with the term “control logic” to refer to any circuitry or blocks that performs control functions and/or other functions associated with performing operations associated with memory devices. The control logic can include firmware and/or software executed or implemented in hardware circuits. In this disclosure, the control logic in some examples can include the controllers (e.g., local controller, system controller, etc.). In other examples, the control logic can include other blocks or circuitry (e.g., sense amplifiers, latches, buffers, registers, decoders, etc.), but not the array of memory cells.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
an array of memory cells comprising a plurality of memory blocks, wherein the plurality of memory blocks comprises a first memory block;
a memory controller;
a first switch connected to the first memory block, wherein the memory controller is configured to select or unselect the first memory block via the first switch;
a first ground line shared among the plurality of memory blocks; and
a second switch connected between the first ground line and the first switch, the second switch being configured to electrically couple the first memory block to the first ground line via the first switch,
wherein the memory controller is configured to cause the second switch to activate, and after activation, disconnect the first memory block from the first ground line shared among the plurality of memory blocks.

2. The memory device of claim 1, further comprising a latch coupled to the second switch, the latch being configured to:
store data representing whether the first memory block is a defective memory block, and
provide, based on the stored data representing whether the first memory block is a defective memory block, a first control signal to the second switch to connect the first memory block to, or disconnect the first memory block from, the first ground line.

3. The memory device of claim 2, wherein the second switch comprises a first terminal connected to the first switch, a second terminal connected to the first ground line, and a control terminal configured to receive the first control signal.

4. The memory device of claim 2, further comprising:
a level shifter coupled to the latch to receive an output signal of the latch, wherein the level shifter is configured to shift a voltage level of the output signal of the latch to a different voltage level.

5. The memory device of claim 2, wherein the first control signal is an internal signal of the latch.

6. The memory device of claim 1, wherein the second switch comprises a low-voltage NMOS (N-type metal-oxide semiconductor) transistor.

7. The memory device of claim 6, wherein the low-voltage NMOS transistor has a size that is smaller than a transistor of the first switch.

8. The memory device of claim 1, further comprising a third switch coupled to the second switch and the first switch, wherein:
the third switch is controllably activated based on a second control signal representing an operation having a voltage exceeding a breakdown threshold of the second switch, and
the third switch, after activation, connects the first memory block to a second ground line.

9. The memory device of claim 8, wherein the third switch comprises a first terminal connected to the first switch, a second terminal connected to the second ground line, and a control terminal configured to receive the second control signal.

10. The memory device of claim 8, wherein the operation having a voltage exceeding the breakdown threshold of the second switch comprises an erase operation.

11. The memory device of claim 8, wherein the second switch comprises a low-voltage NMOS transistor.

12. The memory device of claim 11, wherein the low-voltage NMOS transistor has a size that is smaller than a transistor of the first switch.

13. The memory device of claim 1, wherein the first memory block is a defective memory block having one or more of: a short between a pillar and a select gate, a short between a select gate and a bit line, a short between a source line and a select gate, and a short between a word line and a select gate.

14. The memory device of claim 1, wherein the first memory block further comprises:
one or more select gate drains (SGDs), wherein the first switch of the first memory block is connected to the one or more SGDs.

15. The memory device of claim 14, wherein the one or more SGDs comprise a plurality of ganged SGDs having respective control terminals connected together.

16. A memory system comprising:
a memory device comprising:
an array of memory cells comprising a plurality of memory blocks, wherein the plurality of memory blocks comprises a first memory block;
a memory controller;
a first switch connected to the first memory block, wherein the memory controller is configured to select or unselect the first memory block via the first switch;
a first ground line shared among the plurality of memory blocks; and
a second switch connected between the first ground line and the first switch, the second switch being configured to electrically couple the first memory block to the first ground line via the first switch,
wherein the memory controller is configured to cause the second switch to activate, and after activation, disconnect the first memory block from the first ground line shared among the plurality of memory blocks; and
a system controller coupled to the memory device.

17. A method performed by a memory device comprising a plurality of memory blocks, a memory controller, an isolation switch, a latch, and a first ground line shared between the plurality of memory blocks, the plurality of memory blocks comprising a first memory block, the method comprising:
storing data representing whether the first memory block is a defective memory block in the latch, and
providing, by the latch, based on the stored data representing whether the first memory block is a defective memory block, a control signal to the isolation switch to connect the first memory block to, or disconnect the first memory block from, the first ground line shared between the plurality of memory blocks.

18. The method of claim 17, further comprising:
activating a ground-line switch to connect the first memory block to a second ground line during an operation having a voltage exceeding a breakdown threshold of the isolation switch.
